(19) United States
(12) Patent Application Publication
(10) Pub. No.: US 2001/0026976 A1
(43) Pub. Date: Oct. 4, 2001

(54) Method of fabricating a semiconductor device

(76) Inventor: Yuong-Ho Yang, Cheongju-shi (KR)

Correspondence Address: BIRCH STEWART KOLASCH & BIRCH, PO BOX 747, FALLS CHURCH, VA, 22040-0747, US

(21) Appl. No.: 09/818,773

(22) Filed: Mar. 28, 2001

(30) Foreign Application Priority Data
Mar. 28, 2000 (KR) 2000-15810

(51) Int. Cl. H01L 21/8242; H01L 21/20

(52) U.S. Cl. 438/255; 438/254; 438/398; 438/397

(57) ABSTRACT

A capacitor for a semiconductor device including a lower electrode having a silicon layer with portions initially doped at different doping densities, a plurality of protrusions formed selectively on the lower electrode according to the different doping densities, a dielectric layer over the lower electrode and the protrusions, and an upper electrode over the dielectric layer. After the protrusions are formed, a step of additionally doping the lower electrode to increase the doping density thereof is not required. The silicon layer with portions initially doped at different doping densities allows the protrusions to form more easily, so that the entire surface area of the lower electrode is increased to thus minimize variations in capacitance.

### BACKGROUND OF THE INVENTION

1. Field of Invention

The present invention relates to a method of fabricating a semiconductor device, more particularly, to a method of fabricating a lower electrode of a capacitor in a semiconductor device which enables hemispherical silicon grains (hereinafter abbreviated HSGs) to grow more easily for increasing capacitance of a capacitor by forming a doping density of an amorphous silicon layer of which a central part is heavily doped, of which an upper part is doped lightly, and of which a lower part is doped at the intermediary density therebetween.

The method according to the present invention needs no additional steps of ion doping and diffusion thereof to secure electrical conductivity of amorphous silicon after the formation of HSGs.

Moreover, the method of the present invention improves depletion of a capacitor by providing a uniform density distribution of the lower electrode since the dopants in the amorphous silicon layer are diffused naturally during the deposition of a dielectric layer.

2. Discussion of Related Art

As semiconductor devices become increasingly more highly integrated, various semiconductor elements, such as a dynamic RAM (DRAM) cell, also decrease in size. Thus, the area occupied by a capacitor, e.g., for a DRAM cell, is reduced as well. Therefore, a surface of a lower or storage electrode for a capacitor is formed irregular in shape in order to obtain the required capacitance.

In order to obtain a maximum surface area of the lower electrode, a technique called “Surface Area Enhanced Silicon” (hereinafter abbreviated as SAES) is used to form a plurality of protruding parts on the surface of the lower electrode by forming “Hemispherical Silicon Grains” (hereinafter abbreviated HSGs) on the exposed surface of the lower electrode.

One of the most important factors in performing the SAES technique, which is generally used to increase a surface area of a lower electrode, is to maximize the density of the SAES and its grain size to secure maximum capacitance while the electrical characteristics of the capacitor are maintained.

In order to form HSGs on a surface of amorphous silicon, nuclei are generated on the surface and silicon atoms migrate to the respective nuclei to form grains. Unfortunately, when HSGs are formed on an amorphous silicon layer doped excessively with predetermined ions, the HSGs fail to grow easily because the doped ions block the migration of silicon atoms. To minimize this problem, the amorphous silicon should be doped less.

The related art technique of SAES maximizes the surface area of the lower electrode by: forming a contact hole by removing a predetermined portion of an insulating interlayer to thus expose a predetermined impurity diffusion region; forming polysilicon and amorphous silicon to a predetermined thickness on the insulating interlayer having the contact hole; forming a basic frame of a lower electrode by patterning the polysilicon and amorphous silicon using a hard mask of silicon oxide; and then by forming a plurality of HSGs on the basic frame. Then, a capacitor for a DRAM or the like in a semiconductor device is completed by forming a dielectric layer and an upper electrode on the lower electrode successively.

Namely, HSGs are formed by first forming an amorphous silicon layer on a substrate, then applying a gas comprising a silicon species to the amorphous silicon layer at high vacuum ambience, and then selectively forming nuclei on a surface of the amorphous silicon layer by pyrolyzing the gas at a high temperature causing silicon particles to migrate to the respective nuclei.

Here, negative ion gases of an intrusive type which are pyrolyzed at a high temperature of over 700° C. are diffused within the amorphous silicon layer and the crystalline silicon layer to increase the doping density of the amorphous silicon layer because the HSGs and the amorphous silicon layer near the HSGs are doped lightly. After being formed by depositing silicon nitride of Si₃N₄ on the lower electrode, the dielectric layer undergoes oxidization to improve its layer characteristics. Then, an upper electrode is formed on the dielectric layer.

When HSGs are formed on the amorphous silicon layer doped with negative ions to increase the surface area of a lower electrode of a capacitor according to the related art, there is a difference of negative ion density between the upper layer and the lower layer of the dielectric layer. The difference in density is caused by the low doping density of the lower layer where the HSGs will be formed.

The so-called capacitor depletion occurs when the capacitance of the capacitor varies when about ±1.5V is applied to the upper layer thereof. As the doping density difference between the upper and lower layers increases, capacitor depletion also increases. Thus, to decrease capacitor depletion after the HSGs are formed on a surface of the amorphous silicon layer, the amount of negative ions in the lower layer is increased by additionally doping the HSGs and amorphous silicon layer with negative ions.

In this case, negative ion doping is generally carried out by thermal treatment or by another method of forming negative ions via a plasma state. By such methods, negative ions formed by pyrolyzing an ionizable gas at a high temperature are diffused into the amorphous or crystalline silicon layer.

FIGS. 1A to 1F show cross-sectional views of fabricating a capacitor having a lower electrode where HSGs are formed in a semiconductor device according to the related art.

Referring to FIG. 1A, after a field oxide layer 11 has been formed on a p-type silicon substrate 10 of a semiconductor material, a gate insulating layer 12 of silicon oxide, a gate electrode 13 of doped polysilicon, a gate sidewall spacer 15 of oxide, and an impurity diffusion region 14 doped heavily with n-type impurities such as arsenic (As) and phosphorus (P) are formed to thus fabricate a MOSFET (metal oxide semiconductor field effect transistor).

An insulating interlayer 16 comprising oxide material is formed on the silicon substrate 10 that includes the MOSFET. In this case, a bit line 17 electrically connected to the impurity diffusion region 14, is formed inside the insulating interlayer 16. Then, steps of fabricating a capacitor for completing a DRAM cell in a semiconductor device are carried out.

First, a buffer nitride layer 18 functioning as an etch stop layer is formed on the insulating interlayer 16 by chemical vapor deposition (hereinafter abbreviated as CVD). And, a first sacrificing layer 19 comprising oxide material is deposited on the buffer nitride layer 18 to a predetermined thickness. Then, the first sacrificing layer 19 is coated with a photoresist layer (not shown). A photoresist pattern (not shown) is formed by exposure and development and is aligned over the impurity diffusion region 14, which eventually will be connected electrically to the capacitor. A contact hole exposing the impurity region 14 (doped heavily with n-type impurties) is formed by successively removing exposed portions of the first sacrificing layer 19, the buffer nitride layer 18, and the insulating interlayer 16 by anisotropic etching, such as dry etching or the like, using the photoresist pattern as an etch mask.

After the photoresist pattern has been removed, a first conductive layer 20 is formed on the first sacrificing layer 19 and through the contact hole thereof, by depositing a polysilicon doped with n-type impurities such as phosphorus (P) to a predetermined thickness using CVD. In this case, the first conductive layer 20 of polysilicon is deposited to a thickness insufficient to completely fill up the contact hole. Then, a second sacrificing layer 21 is formed on the first conductive layer 20 by depositing an oxide material to completely fill up the contact hole.

Thereafter, portions of the second sacrificing layer 21 and the first conductive layer 20 are patterned by photolithography so that portions of the second sacrificing layer 21 and the first conductive layer 20 remaining on the first sacrificing layer 19 and extending through the contact hole region define a lower structure of a lower electrode of the capacitor.

Referring to FIG. 1B, a second conductive layer 22 is formed on the first sacrificing layer 19 including the remaining second sacrificing layer 21 and first conductive layer 20 by depositing to a predetermined thickness, an amorphous silicon material doped with n-type impurities, such as phosphorus, for electric conduction. In this case, the amorphous silicon of the second conductive layer 22 is doped lightly to allow the easy growth of HSGs thereon. Otherwise, it would be difficult for HSGs to grow large because the heavy concentration of dopants inhibits silicon particles from migrating to the nuclei.

Referring to FIG. 1C, a sidewall spacer 220 is formed by performing etch back on the second conductive layer 22 of amorphous silicon, wherein the sidewall spacer 220 consists of the remaining second conductive layer 22 at the sides of the remaining second sacrificing layer 21 and first conductive layer 20. The sidewall spacer 220 is in the shape of a pillar forming an upper structure of the lower electrode of a capacitor. Then, portions of the first conductive layer 20 between the pad nitride layer 18 and the sidewall spacer 220 are exposed via wet etching, which removes the second sacrificing layer 21 and the first sacrificing layer 19 on the pad nitride layer 18. Thus, a surface on which a dielectric layer will be later deposited on a lower electrode having a crown type is exposed.

Referring to FIG. 1D, protrusions comprising a plurality of hemispherical silicon grains (hereinafter abbreviated as HSGs) 230 are formed on the exposed lower electrode consisting of the first conductive layer 20 and sidwall spacer 220, to achieve “Surface Area Enhanced Silicon” (SAES) for enhancing the surface area of the lower electrode. The HSGs are formed by applying SiH₄ gas on an exposed surface of the first conductive layer 20 and the sidewall spacer 220.

Referring to FIG. 1E, it is desirable to prevent capacitor depletion due to the density difference between the upper and lower layers above and below the dielectric layer. To do so, the doping density of the HSGs 230 and the lower electrode including the sidewall spacer 220 (each being formed of amorphous silicon) is increased by carrying out additional impurity doping with negative ions, such as phosphorus ions, after having removed a naturally formed oxide layer on the surface of the lower electrode with the HSGs. The additional doping is essential because the incubation time for crystallizing amorphous silicon needs to be lengthened in order to form the HSGs.

The temperature during the deposition of a silicon layer or the doping density should be low, provided that the incubation time is extended. In this case, intrusive ions generated from a gas for forming negative ions by pyrolysis at a high temperature of over 700° C. are diffused within the amorphous and crystalline silicon layers of the sidewall spacer 220 and the first conductive layer 20, respectively, to increase the doping density of the silicon layers since the HSGs and the silicon layer around the HSGs are doped lightly.

Referring to FIG. 1F, a thin dielectric layer 24 is formed on an exposed surface of a final lower electrode structure consisting of the HSGs 230, the sidewall spacer 220 and first conductive layer 20. In this case, the dielectric layer 24 is formed by depositing a nitride (Si₃N₄) layer and by oxidizing a surface of the nitride layer to form a layer of an oxygen-nitride-oxygen (O—N—O) structure. Then, an upper electrode 25 being a plate electrode is formed by depositing a third conductive layer on the dielectric layer 24. The upper electrode 25 is formed of doped polysilicon or metal such as TiN or the like, to thus completely form the capacitor.

Unfortunately, in the method of fabricating a capacitor according to the related art, the additional step of doping a lower electrode is necessary for preventing capacitor depletion, which makes the overall processing complicated.

Moreover, the additional doping step in the related art carried out at a high temperature may degrade the characteristics of various semiconductor devices, such as transistors, formed beneath the capacitor.

### SUMMARY OF THE INVENTION

Accordingly, the present invention is directed to a method of fabricating a semiconductor device that substantially obviates one or more of the problems due to limitations and disadvantages of the related art.

The present invention provides a method of fabricating a semiconductor device with HSGs for increasing capacitance, in which the HSGs are grown by forming an amorphous silicon layer having portions with different doping densities. For example, the lower electrode of a capacitor according to the present ivnention has a central part that is heavily doped, an upper part that is doped lightly, and a lower part that is doped at an intermediary density therebetween. The present invention requires no additional steps of ion doping and diffusion thereof to secure electrical conductivity of amorphous silicon after formation of the HSGs, yet improves the depletion of a capacitor by providing a uniform density distribution of a lower electrode, since the dopants in the amorphous silicon layer are diffused naturally during the deposition of a dielectric layer.

Also, the present invention provides a method of fabricating a semiconductor device which provides sufficient impurity doping density of a conductor, and enables formation of HSGs for enhancing the surface area of a conductor, e.g., the lower electrode of a capacitor in a semiconductor device.

Additional features and advantages of the invention will be set forth in the description which follows and in part will be apparent from the description, or may be learned by practice of the invention by those skilled in the art. The other advantages of the invention will be realized and attained by the example structures particularly pointed out in the written description and claims hereof as well as the appended drawings.

To achieve these and other advantages, and in accordance with the present invention as embodied and broadly described, the present invention includes: forming on a substrate, a first amorphous silicon layer doped with impurity ions at a first impurity density forming on the first amorphous silicon layer; forming on the first amorphous silicon layer, a second amorphous silicon layer doped with impurity ions at a second impurity density that is higher than the first impurity density; forming on the second amorphous silicon layer, a third amorphous silicon layer doped with impurity ions at a third impurity density that is lower than the first impurity density; forming a predetermined pattern that retains portions of the first to third amorphous silicon layers; forming hemispherical silicon grains on an exposed surface of the predetermined pattern; and diffusing the impurity ions among the hemispherical silicon grains and the predetermined pattern so that the density of the impurity ions is uniform in the hemispherical silicon grains and in the predetermined pattern.

Preferably, the step of diffusing the impurity ions further includes the steps of depositing a silicon nitride layer on surfaces of the hemispherical silicon grains and the predetermined pattern at a first high temperature, and oxidizing the silicon nitride layer at a second high temperature.

In another aspect, the present invention includes forming an insulating layer on a semiconductor substrate having a contact hole exposing a portion of the substrate; forming a first conductive layer in contact with a predetermined portion of the semiconductor substrate (due to the contact hole) on the insulating layer; forming a first amorphous silicon layer doped with impurity ions at a first impurity density on the first conductive layer; forming a second amorphous silicon layer doped with the impurity ions at a second impurity density higher than the first impurity density on the first amorphous silicon layer; forming a third amorphous silicon layer doped with the impurity ions at a third impurity density lower than the first impurity density on the second amorphous silicon layer; forming a lower electrode by selectively removing the first to third amorphous silicon layers and the first conductive layer; forming hemispherical silicon grains on an exposed surface of the lower electrode; forming a dielectric layer on exposed surfaces of the lower electrode and the hemispherical silicon grains; and forming an upper electrode of a second conductive layer on the dielectric layer.

Preferably, the step of forming a dielectric layer further comprises: depositing a silicon nitride layer on surfaces of the hemispherical silicon grains and the lower electrode at a first high temperature, and oxidizing the silicon nitride layer at a second high temperature, wherein the impurity ions diffuse naturally.

In a further aspect, the present invention includes the steps of forming an insulating layer on a semiconductor substrate having a contact hole exposing a portion of the substrate; forming a first conductive layer in contact with the predetermined portion of the semiconductor substrate on the insulating layer; patterning the first conductive layer to remain in the contact hole and to be extended on a top surface portion of the insulating layer; forming a pillar at a side of the remaining first conductive layer, wherein the pillar comprises a first amorphous silicon layer doped with impurity ions at a first impurity density, a second amorphous silicon layer doped with impurity ions at a second impurity density higher than the first impurity density, and a third amorphous silicon layer doped with impurity ions at a third impurity density lower than the first impurity density, and wherein the first to third amorphous silicon layers are stacked successively; forming hemispherical silicon grains on exposed surfaces of the first conductive layer and the pillar; forming a dielectric layer on exposed surfaces of the pillar and the hemispherical silicon grains; and forming an upper electrode of a second conductive layer on the dielectric layer.

Preferably, the formation of the pillar further comprises: forming a sacrificing layer on the first conductive layer formed on a substance of which an etch rate differs greatly from that of the insulating layer; patterning the sacrificing layer and the first conductive layer to remain in the contact hole and to be extended on a top surface portion of the insulating layer; forming a first amorphous silicon layer doped with impurity ions at a first impurity density on the insulating layer including the remaining sacrificing layer and a first conductive layer pattern of the remaining first conductive layer; forming a second amorphous silicon layer doped with impurity ions at a second impurity density higher than the first impurity density on the first amorphous silicon layer; forming a third amorphous silicon layer doped with impurity ions at a third impurity density lower than the first impurity density on the second amorphous silicon layer; patterning the first to third amorphous silicon layers so that these layers remain only at side portions of the remaining sacrificing layer and the first conductive layer pattern; and removing the remaining sacrificing layer.

It is to be understood that both the foregoing general description and the following detailed description are exemplary and explanatory, and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the features of the invention.

In the drawings:

FIGS. 1A to 1F show cross-sectional views of fabricating a capacitor having a lower electrode where HSGs are formed in a semiconductor device according to the related art;

FIGS. 2A to 2G show cross-sectional views of fabricating a capacitor having a lower electrode where HSGs are formed in a semiconductor device according to the present invention; and

FIG. 3 shows a graph of the doping density of a lower electrode consisting of amorphous silicon of which the doping density distribution is non-uniform according to the present invention.

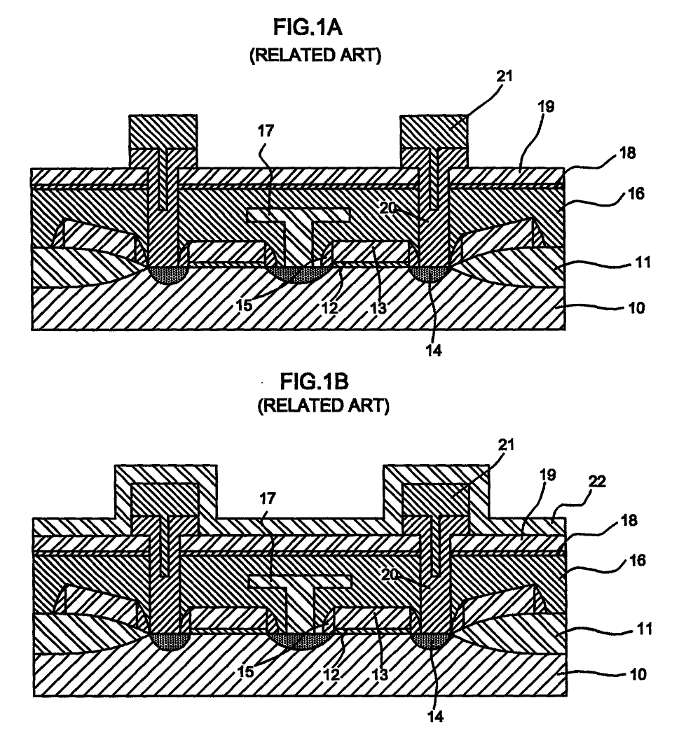

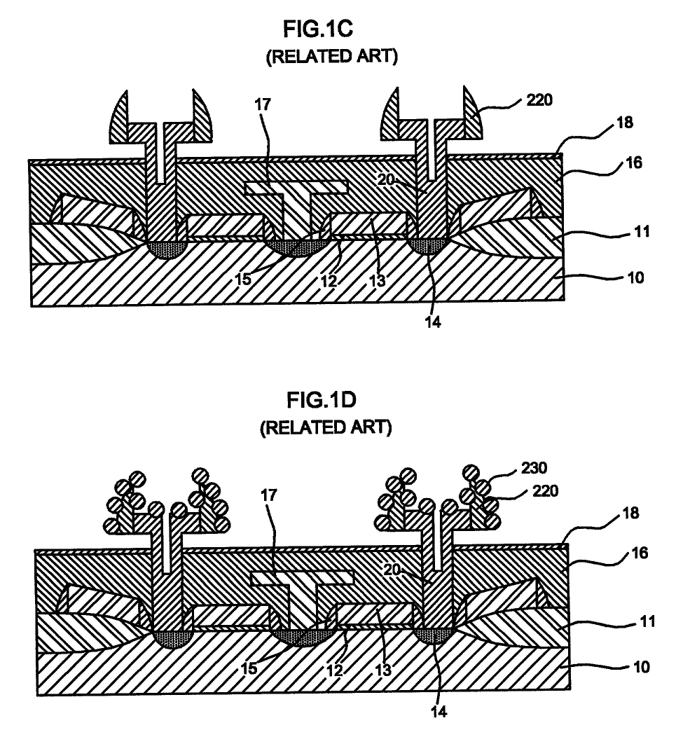

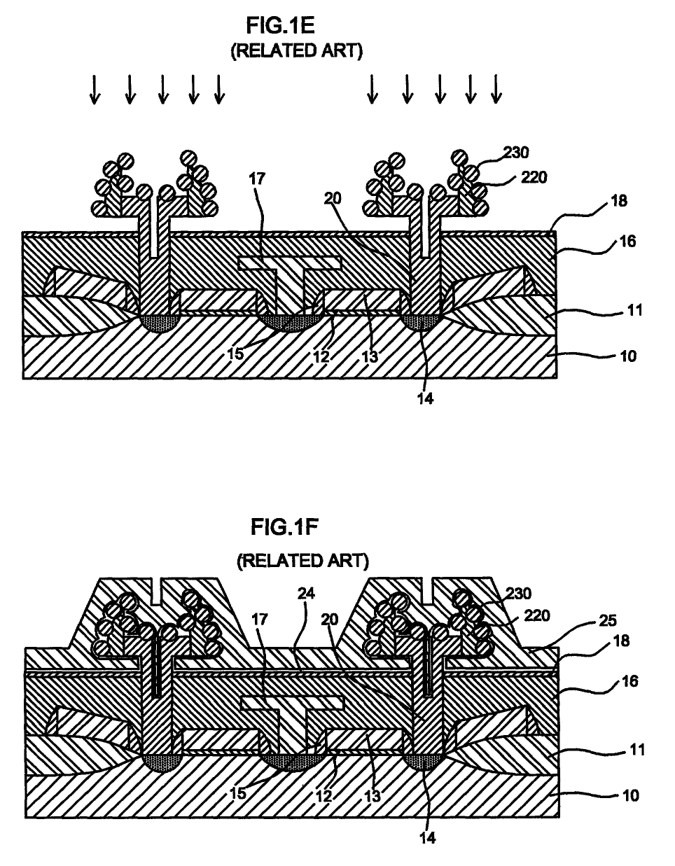

### DETAILED DESCRIPTION OF PREFERRED EMBODIMENTS

Reference will now be made in detail to the preferred embodiments of the present invention, examples of which are illustrated in the accompanying drawings.

The present invention relates to a capacitor having HSGs formed by a method which prevents capacitor depletion that causes capacitance variance, which increases a deposition area of a dielectric layer, and does not require an additional step of doping a lower electrode. The capacitor is achieved by forming a lower electrode of amorphous silicon having different doping densities, by forming HSGs on a surface of the amorphous silicon, and by forming a dielectric layer and an upper electrode thereon.

However, instead of carrying out an additional ion implantation step to increase electric conductivity after the formation of HSGs on an amorphous silicon layer constructing a lower electrode according to the related art, the present invention increases the doping density of the capacitor lower electrode by forming a plurality of amorphous silicon layers each having different doping density distributions, which allow HSGs to be grown more easily on the amorphous silicon layer, and then by obtaining a uniform doping density distribution by self-diffusion.

The present invention forms stacked amorphous silicon layers, which will become a lower electrode of a capacitor, of which the doping density distribution varies in the respective layers to give amorphous silicon electric conductivity with impurity ions.

In this case, the doping density distribution of the multi-layered amorphous silicon can be, for example, high density, middle density and low density. Such density distribution is achieved by stacking in-situ doped amorphous silicon layers successively or by carrying out the steps of forming an undoped amorphous silicon layer, and then implanting impurity ions into the undoped amorphous silicon layer at various impurity doses.

When the amorphous silicon layers are formed using the undoped amorphous silicon, a lower amorphous silicon layer, a middle amorphous silicon layer and an upper amorphous silicon layer are doped at middle, heavy and light doses, respectively.

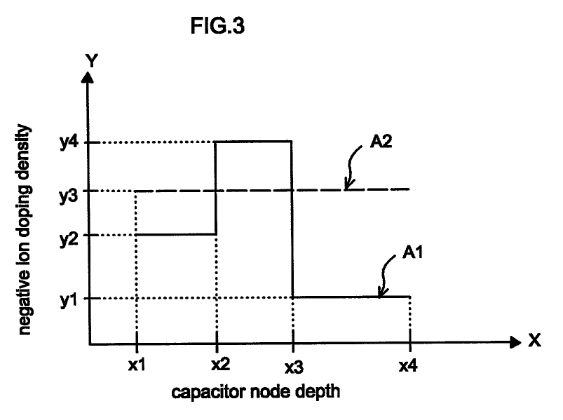

Then, HSGs are formed on a surface of a lower electrode formed by patterning the doped amorphous silicon layers. In this case, the HSGs grow with ease because most of the HSGs tend to be formed at the amorphous silicon, which is doped at the light or middle densities which are lower than the average doping density of the related art as shown in FIG. 3.

A dielectric layer is deposited on a surface of the lower electrode of which an overall exposed area is increased. In this case, when the dielectric layer is formed of silicon nitride, the deposition and oxidation temperature of nitride is very high. Thus, the entire doping density of the amorphous silicon layer becomes uniform because the impurity ions in the respective amorphous silicon layers diffuse from high to low density during the formation of the silicon nitride layer.

Accordingly, the present invention (again, fabricating a capacitor having a particular lower electrode structure minimizes the difference of the negative ion doping density between the upper and lower layers above and below the dielectric layer) does not require an additional doping step for evening out or balancing the doping density of the upper and lower electrodes, prevents capacitor depletion because the entire doping density of the amorphous silicon layer becomes even owing to self-diffusion, and prevents characteristic distortions of devices, such as transistors, which would be caused by additional thermal processing, thereby simplifying the overall steps of fabricating a capacitor.

The present invention can be constructed using the following steps.

First, a lower or storage electrode having a 3-dimensional structure, such as a crown, a cylinder or the like, is formed to increase capacitance of a capacitor which will be part of a semiconductor memory device, such as a DRAM.

A plurality of amorphous silicon layers, which are stacked and doped at different doping densities (e.g., with negative ions of dopants) are formed successively to thus fabricate a lower electrode of a capacitor. Amorphous silicon is used to enhance the specific areas where HSGs will be formed to grow on the lower electrode.

In the related art, HSGs are formed by forming a lightly doped amorphous silicon layer of which the doping density is uniform, and by forming the HSGs on a surface of the uniformly lightly doped amorphous silicon layer. Therefore, the related art requires an additional step of doping a lower electrode to prevent capacitor depletion due to the doping density difference between the lower and upper electrodes between which a dielectric layer is inserted, thus making the overall manufacaturing process complicated. The characteristics of devices, such as transistors, are degraded in the related art because the additional doping step must be performed at a high temperature, which affects the semiconductor devices beneath the capacitor.

Accordingly, the present invention employs a plurality of amorphous silicon layers of a stacked structure defining a doping density distribution by forming the amorphous silicon layers in a step by step process.

For instance, after forming a first amorphous silicon layer doped at a medium density, a second amorphous silicon layer doped heavily is formed on the first amorphous silicon layer. Then, a third amorphous silicon layer which is doped lightly or undoped is formed on the second amorphous silicon layer.

The lower electrode is formed by patterning the first to third amorphous silicon layers by photolithography. In this case, exposed portions of the lower electrode are mainly constituted by the lightly doped third amorphous silicon layer and the medium doped first amorphous silicon layer.

Then, HSGs are formed on the exposed surface of the lower electrode by a general growing method. Namely, after silicon nuclei have been formed selectively on the surface of the amorphous silicon layers by pyrolyzing silicon gas in a deposition apparatus under a vacuum ambience, the HSGs are formed by migrating silicon particles around the respective nuclei.

In this case, the HSGs grow with ease owing to the smooth mobility of silicon atoms because the specific doping density near the nuclei where the HSGs grows according to the present invention is lower than that of the related art.

Moreover, thermal treatments such as annealing for crystallization may be performed on the amorphous silicon layers after the formation of the HSGs to thus minimize device characteristic degradation.

Then, a dielectric layer, e.g., of silicon nitride (Si₃N₄) is formed and oxidized on the lower electrode including the HSGs. In this case, as the deposition and oxidation of the silicon nitride are carried out at a high temperature, dopants in the heavily doped second amorphous silicon layer diffuse into the lightly doped third amorphous silicon layer and the medium doped first amorphous silicon layer, thereby providing an increased uniform doping density of the entire lower electrode.

Finally, an upper electrode of doped polysilicon and the like is formed on the dielectric layer. Examples of non-uniform doping density distributions of amorphous silicon layers are shown in FIG. 3 according to the present invention.

Referring to FIG. 3, the X axis indicates the depth from a lower amorphous silicon layer through a middle amorphous silicon layer up to an upper amorphous silicon layer that together define a lower electrode of a capacitor, while the Y axis shows the negative ion (dopant) density corresponding of each amorphous silicon layer.

The portions (x1-x2), (x2-x3), and (x3-x4) show thicknesses of the medium doped, heavily doped, and lightly doped amorphous silicon layers, respectively.

The value ‘y1’ of the Y axis is below 1.0 E20 atoms/cm³, ‘y4’ is 1.0 E21 atoms/cm³, ‘y2’ lies between 1.0 E20 atoms/cm³ and 1.0 E21 atoms/cm³, and ‘y3’ lies around the middle value between ‘y2’ and ‘y4’.

A density line ‘A1’ shows a doping density of the first to third amorphous silicon layers before depositing a dielectric layer of silicon nitride, and the density line ‘A2’ indicates a doping density of the first to third amorphous silicon layers after the deposition and oxidation of the silicon nitride layer.

As shown in the graph, the average of the doping density of the first amorphous silicon layer is ‘y2’. The average doping density of the second amorphous silicon layer is ‘y4’ which is the highest, while the average doping density of the third amorphous silicon layer is ‘y1’ which is the lowest. These average distributions are of the respective layers before the deposition of the silicon nitride layer.

Therefore, an exposed area of the lower electrode where the dielectric layer will be formed mainly comprises the medium doped first amorphous silicon layer and the lightly doped third amorphous silicon layer, thereby making the HSGs grow with ease.

After the HSGs have been formed on a surface of the lower electrode (again, formed of the first to third amorphous silicon layers), a dielectric layer of silicon nitride is formed on the exposed surface of the lower electrode. Then, the silicon nitride layer undergoes oxidation to form an oxide-nitride-oxide (O—N—O) structure.

In this case, as the deposition and oxidation are carried out at high temperatures, a uniform doping density (y3) of the entire lower electrode is achieved since dopants in the first to third amorphous silicon layers diffuse spontaneously from high to low density.

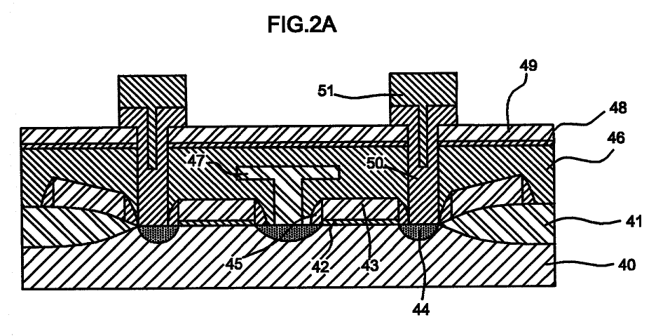

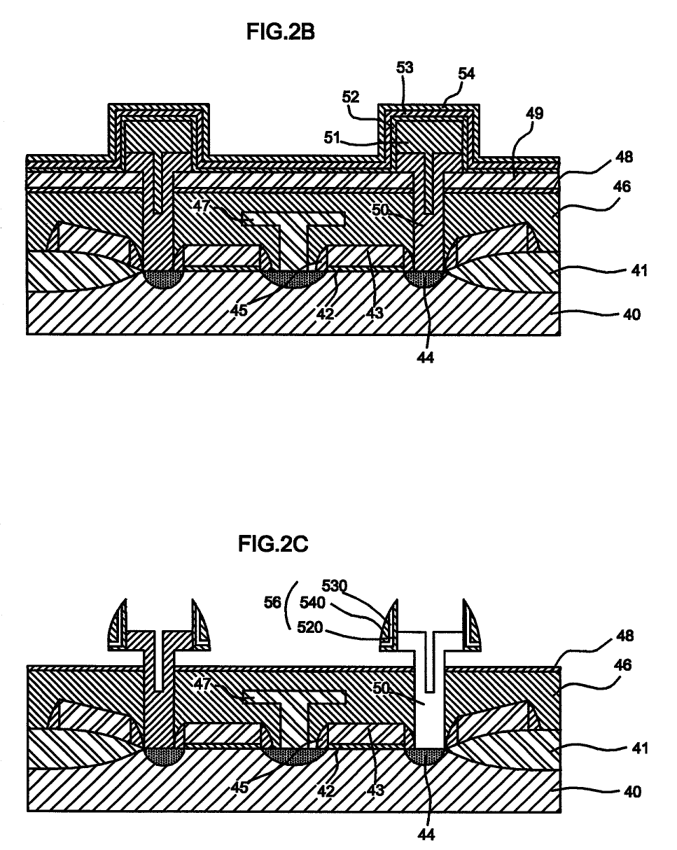

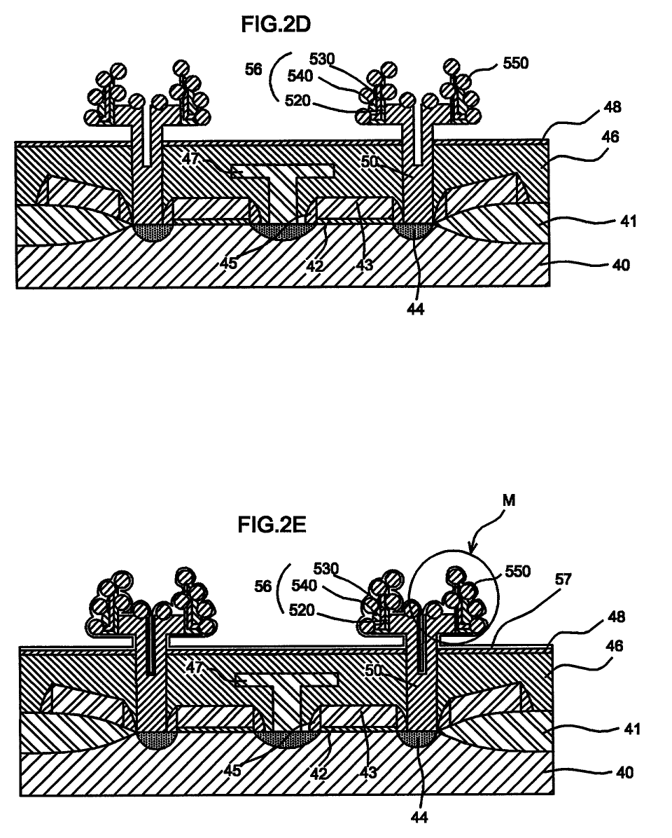

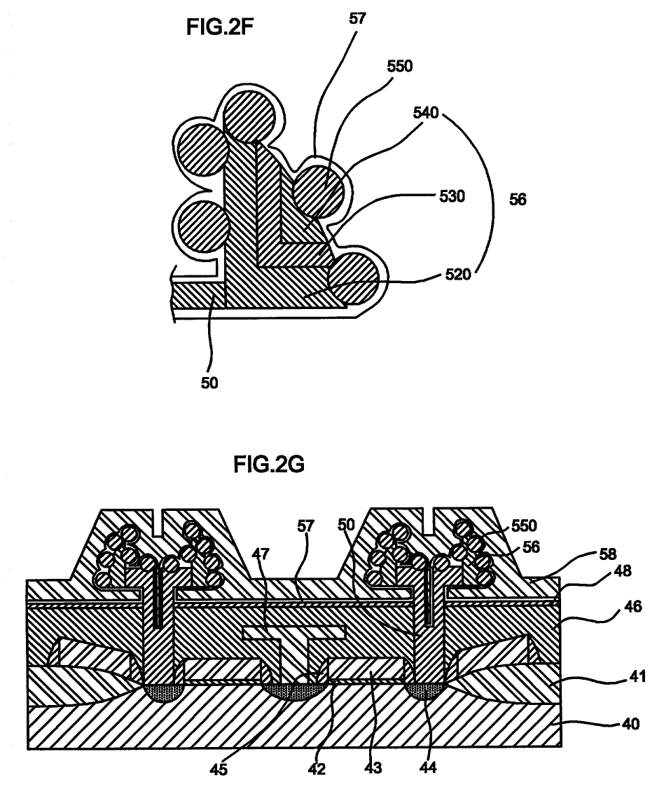

FIGS. 2A to FIGS. 2G show cross-sectional views of fabricating a capacitor having a lower electrode where HSGs are formed in a semiconductor device according to the present invention.

Referring to FIG. 2A, after a field oxide layer 41 has been formed on a p-type silicon substrate 40 of the semiconductor device, a gate insulating layer 42 of silicon oxide, a gate electrode 43 of doped polysilicon, a gate sidewall spacer 45 of oxide, and an impurity diffusion region 44 doped heavily with n-type impurities such as As or P are formed to fabricate a MOSFET (metal oxide semiconductor field effect transistor).

An insulating interlayer 46 of oxide material is formed on the silicon substrate 40 that includes the MOSFET. In this case, a bit line 47 connected electrically to the impurity diffusion region 44 is formed inside the insulating interlayer 46. Then, steps of fabricating a capacitor for completing a DRAM cell in a semiconductor device are carried out. First, a buffer nitride layer 48 being an etch stop layer is formed on the insulating interlayer 46 by CVD. And, a first sacrificing layer 49 of an oxide material is deposited on the buffer nitride layer 48 to a predetermined thickness. In this case, the thickness of the first sacrificing layer 49 depends on an interval between a distal part of the lower electrode and the insulating interlayer 46. Then, the first sacrificing layer 49 is coated with a photoresist layer (not shown). After a photoresist pattern (not shown) has been formed by exposure and development to expose the impurity diffusion region 44 (which will be connected electrically to a lower electrode of the capacitor), a contact hole exposing the impurity region 44 is formed by successively removing exposed portions of the first sacrificing layer 49, the buffer nitride layer 48, the insulating interlayer 46 by anisotropic etching, such as dry etching or the like, using the photoresist pattern as an etch mask.

After the photoresist pattern has been removed, a first conductive layer 50 is formed on the first sacrificing layer 49 and through the contact hole thereof, by depositing a polysilicon doped with n-type impurities such as phosphorus (P) to a predetermined thickness by CVD. In this case, the first conductive layer 50 of polysilicon is deposited to the thickness such that the contact hole is not completely filled, so that an exposed area of a lower electrode can be extended to the inside of the contact hole.

A second sacrificing layer 51 is formed to fill up the contact hole by depositing an oxide material on the first conductive layer 50. The second sacrificing layer 51 will be patterned to be a support of a pillar of a lower electrode of a crown type.

Then, the second sacrificing layer 51 and the first conductive layer 50 are patterned successively by photolithography so that portions of the second sacrificing layer 51 and the first conductive layer 50 which define a lower structure of a lower electrode of the capacitor remain on the first sacrificing layer 49 and extend through the contact hole region.

Referring to FIG. 2B, a first amorphous silicon layer 52 doped at a medium density using n-type impurities such as phosphorus ions, is deposited to a predetermined thickness on the first sacrificing layer 49 including the remaining second sacrificing layer 51 and first conductive layer 50.

In this case, the doping density of the first amorphous silicon layer 52 has a middle value ranging between 1.0 E20 atoms/cm³ and 1.0 E21 atoms/cm³ to allow the HSGs to grow easy thereon. And, the first amorphous silicon layer 52 may be formed by depositing in-situ doped amorphous silicon or by depositing undoped amorphous silicon and doping the undoped amorphous silicon with phosphorus ions at a predetermined dose. If the doping density of the first amorphous silicon layer 52 (which will become one of the main portions for growing HSGs is large), it is difficult for HSGs to grow large since heavily doped polysilicon inhibits silicon particles from migrating around the nuclei.

A second amorphous silicon layer 53, heavily doped with impurities such as phosphorus ions, is deposited on the first amorphous silicon layer 52. In this case, the second amorphous silicon layer 53 should be doped to be over 1.0 E21 atoms/cm³, and is formed by the same method of forming the first amorphous silicon layer 52.

The second amorphous silicon layer 53 is heavily doped because an exposed portion of the second amorphous silicon layer 53 is relatively smaller than that of the first amorphous silicon layer 52 or follows the lightly doped third amorphous silicon layer when HSGs are formed thereon. Thus, the heavily doped second amorphous silicon layer 53 has less influence on growing HSGs for enhancing a surface area of a lower electrode which is formed by patterning the first to third amorphous silicon layers which are doped differently.

However, the second amorphous silicon layer 53 plays a great role indoping a lower electrode at an uniform density higher than that of the related art. This is because dopants in the second amorphous silicon layer 53 diffuse into the first and third amorphous silicon layers 52, 54 sufficiently during annealing after the formation of HSGs and the deposition and oxidation of a nitride layer.

Then, a third amorphous silicon layer 54 lightly doped with impurities such as phosphorus ions is deposited on the second amorphous silicon layer 53. In this case, the third amorphous silicon layer 54 should be doped under 1.0 E20 atoms/cm³ or may be formed on undoped amorphous silicon, and is formed by the same method as forming the first amorphous silicon layer 52.

The reason why the P ion doping density of the third amorphous silicon layer 54 is low or zero is that the small dopant density of the third amorphous silicon layer 54 (which again is one of the major portions on which HSGs are formed) makes silicon particles migrate easily around the nuclei, enabling the formation of large HSGs.

Referring to FIG. 2C, the third to first amorphous silicon layers are etched back, thereby forming a sidewall spacer 56 formed of the first to the third amorphous silicon layers 540, 530, and 520 remaining only at the sides of the remaining second sacrificing and first conductive layers 51 and 50. In this case, the sidewall spacer 56 comprises a pillar part of an upper structure of the lower electrode of a capacitor, and a surface of the remaining first sacrificing layer 49 is exposed.

Then, surfaces of the first conductive layer 50 on the pad nitride layer 48 and the sidewall spacer 56 are exposed by removing the second and first sacrificing layers 49, 51 of oxide by wet etching, thereby exposing a surface on which a dielectric layer will be deposited, of a lower electrode of a crown type.

Referring to FIG. 2D, a plurality of HSGs 550 are formed on a surface of the exposed lower electrode to obtain SAES for enhancing the surface area of the lower electrode formed of the remaining first conductive layer 50 and the sidewall spacer 56. In this case, the HSGs 550 are formed by flowing SiH₄ gas on the exposed surfaces of the sidewall spacer 56 and first conductive layer 50.

Specifically, the HSGs are formed by a general method of growing the HSGs on an exposed surface of the lower electrode. Namely, after silicon nuclei have been formed selectively on the exposed surfaces of the amorphous silicon layers 520, 530, and 540 by pyrolyzing silicon gas in a deposition apparatus under a vacuum ambience, the HSGs 550 are formed as silicon particles migrate around the respective nuclei.

Here, the HSGs grow with ease owing to smooth mobility of silicon atoms since the specific doping density near the nuclei where the HSGs grow according to the present invention is lower than that of the related art. Moreover, thermal treatment such as annealing for crystallization may be performed on the amorphous silicon layers after the formation of the HSGs.

Referring to FIG. 2E, after having removed a natural oxide layer on the surface of the lower electrode including the HSGs 550, a dielectric layer 57 is formed thinly over an exposed surface of a final lower electrode formed of the HSGs 550, the sidewall spacer 56 (corresponding to the remaining first to third amorphous silicon layers 540, 530, and 520), and the first conductive layer 50.

Here, the dielectric layer 57 is formed by depositing silicon nitride (Si₃N₄) and by oxidizing a surface of the silicon nitride to obtain an O—N—O structure. As the deposition and oxidation of the silicon nitride are carried out at a high temperature, dopants in the remaining first to third amorphous silicon layers 540, 530, and 520 undergo self-diffusion to provide an increased uniform doping density of the sidewall spacer 56 forming the pillar of the lower electrode. An area where such a mechanism of self-diffusion takes place is designated by ‘M’ in FIG. 2E and magnified in FIG. 2F.

Referring to FIG. 2F, a pillar of the lower electrode is constructed with the remaining first to third amorphous silicon layers 520, 530, and 540 at the lateral sides of the first conductive layer 50. The first amorphous silicon layer 520 is doped at a medium density, the second amorphous silicon layer 530 is doped heavily, and the third amorphous silicon layer 540 is doped lightly or undoped.

A plurality of HSGs 550 are formed on a surface of the lower electrode of a multi-layered structure. A silicon nitride layer 57, being a dielectric of a capacitor, is formed over the HSGs 550 and the first to third amorphous silicon layers 520, 530, and 540.

Although not shown in the FIG. 2F, silicon oxide is additionally formed on the silicon nitride layer 57 using high temperature oxidation to improve the dielectric characteristics. Self-diffusion occurs from high to low density regions of the first to third amorphous silicon layers 520, 530, and 540 which are doped with phosphorus ions at different densities because of the deposition and oxidation at high temperature, thereby providing a uniform doping density of the overall lower electrode.

Referring to FIG. 2G, an upper electrode 58 being a plate electrode is formed by depositing a second conductive layer on the dielectric layer 57. In this case, the upper electrode 58 is formed of doped polysilicon or metal such as TiN or the like to thus form a complete capacitor.

Accordingly, the present invention enables hemispherical silicon grains (HSGs) to grow easily for increasing capacitance of a capacitor by forming a doping density of an amorphous silicon layer having a central part that is heavily doped, an upper part that is doped lightly, and a lower part that is doped at an intermediary density therebetween.

Also, the method according to the present invention does not require any additional steps of ion doping and diffusion thereof to secure electrical conductivity of amorphous silicon after the formation of HSGs. Moreover, the method of the present invention improves the depletion of a capacitor by providing a uniform density distribution of a lower electrode, since the dopants in an amorphous silicon layer are diffused naturally during the deposition of a dielectric layer.

It will be apparent to those skilled in the art that various modifications and variations can be made in a method of fabricating a semiconductor device of the present invention without departing from the spirit or scope of the invention. Thus, it is intended that the present invention cover various modifications and variations of this invention provided they come within the scope of the appended claims and their equivalents.

What is claimed is:

1. A method of fabricating a semiconductor device comprising:
forming on a substrate a first amorphous silicon layer doped with impurity ions at a first impurity density;
forming on the first amorphous silicon layer a second amorphous silicon layer doped with impurity ions at a second impurity density higher than the first impurity density;
forming on the second amorphous silicon layer a third amorphous silicon layer doped with impurity ions at a third impurity density lower than the first impurity density;
forming a predetermined pattern by patterning the first to third amorphous silicon layers;
forming hemispherical silicon grains on an exposed surface of the predetermined pattern; and
diffusing the impurity ions among the hemispherical silicon grains and the predetermined pattern so that a density of the impurity ions is uniform in the hemispherical silicon grains and the predetermined pattern.

2. The method according to claim 1, wherein the first to third amorphous silicon layers and the hemispherical silicon grains are doped with negative impurity ions.

3. The method according to claim 1, wherein the impurity ions are phosphorus ions.

4. The method according to claim 3, wherein the first impurity density of the phosphorus ions lies between 1.0E20 and 1.0E21 atoms/cm³, the second impurity density of the phosphorus ions is over 1.0E21 atoms/cm³, and the third impurity density of the phosphorus ions lies between 0.0 and 1.0E20 atoms/cm³.

5. The method according to claim 1, wherein the step of diffusing the impurity ions further comprises:
depositing a silicon nitride layer on surfaces of the hemispherical silicon grains and the predetermined pattern at a first temperature; and
oxidizing the silicon nitride layer at a second temperature.

6. The method according to claim 1, wherein the step of diffusing the impurity ions is achieved by carrying out annealing on the hemispherical silicon grains and the predetermined pattern.

7. The method according to claim 5, wherein after the step of oxidizing the silicon nitride layer, the method further comprises:
forming a conductive layer on the silicon nitride layer wherein the predetermined pattern and the hemispherical silicon grains, the silicon nitride layer, and the conductive layer respectively become a lower electrode, a dielectric layer, and an upper electrode of a capacitor.

8. The method according to claim 7, wherein the conductive layer is formed of doped polysilicon.

9. The method according to claim 1, wherein the hemispherical silicon grains are formed by flowing SiH₄ gases on the exposed surface of the predetermined pattern.

10. The method according to claim 1, wherein the first to third amorphous silicon layers are formed of in-situ doped amorphous silicon at the first to third impurity densities, respectively.

11. The method according to claim 1, wherein the first to third amorphous silicon layers are formed by depositing undoped amorphous silicon and then by doping the undoped amorphous silicon at the first to third impurity densities, respectively.

12. A method of fabricating a semiconductor device comprising:
forming an insulating layer on a semiconductor substrate having a contact hole exposing a portion of the substrate;
forming on the insulating layer a first conductive layer contacting a predetermined portion of the semiconductor substrate;
forming on the first conductive layer a first amorphous silicon layer doped with impurity ions at a first impurity density;
forming on the first amorphous silicon layer a second amorphous silicon layer doped with the impurity ions at a second impurity density higher than the first impurity density;
forming on the second amorphous silicon layer a third amorphous silicon layer doped with the impurity ions at a third impurity density lower than the first impurity density;
forming a lower electrode by patterning the first to third amorphous silicon layers and the first conductive layer, wherein the lower electrode comprises the the first to third amorphous silicon layers and the first conductive layer;
forming hemispherical silicon grains on an exposed surface of the lower electrode;
forming a dielectric layer on exposed surfaces of the lower electrode and the hemispherical silicon grains; and
forming on the dielectric layer an upper electrode using a second conductive layer.

13. The method according to claim 12, wherein the first to third amorphous silicon layers and the hemispherical silicon grains are doped with negative impurity ions.

14. The method according to claim 12, wherein the impurity ions are phosphorus ions.

15. The method according to claim 14, wherein the first impurity density of the phosphorus ions lies between 1.0E20 and 1.0E21 atoms/cm³ the second impurity density of the phosphorus ions is over 1.0E21 atoms/cm³, and the third impurity density of the phosphorus ions lies between 0.0 and 1.0E20 atoms/cm³.

16. The method according to claim 12, wherein the step of forming a dielectric layer further comprises:
depositing a silicon nitride layer on surfaces of the hemispherical silicon grains and the lower electrode at a first temperature; and
oxidizing the silicon nitride layer at a second temperature at which the impurity ions diffuse naturally.

17. The method according to claim 12, further comprising the step of carrying out annealing on the hemispherical silicon grains and the lower electrode to diffuse the impurity ions therebetween.

18. The method according to claim 12, wherein the second conductive layer is formed of doped polysilicon.

19. The method according to claim 12, wherein the hemispherical silicon grains are formed by flowing SiH₄ gases on the exposed surface of the lower electrode.

20. The method according to claim 12, wherein the first to third amorphous silicon layers are formed of in-situ doped amorphous silicon at the first to third impurity densities, respectively.

21. The method according to claim 12, wherein the first to third amorphous silicon layers are formed by depositing undoped amorphous silicon and then by doping the undoped amorphous silicon at the first to third impurity densities, respectively.

22. A method of fabricating a semiconductor device comprising:
forming an insulating layer on a semiconductor substrate having a contact hole exposing a portion of the substrate;
forming on the insulating layer a first conductive layer contacting a predetermined portion of the semiconductor substrate;
patterning the first conductive layer so that the first conductive layer remains in the contact hole and extends on a top surface portion of the insulating layer;
forming a pillar at a side of the remaining first conductive layers wherein the pillar is constructed using a first amorphous silicon layer doped with impurity ions at a first impurity density, a second amorphous silicon layer doped with impurity ions at a second impurity density higher than the first impurity density, and a third amorphous silicon layer doped with impurity ions at a third impurity density lower than the first impurity density, and wherein the first to third amorphous silicon layers are stacked successively;
forming hemispherical silicon grains on exposed surfaces of the remaining first conductive layer and the pillar;
forming a dielectric layer on exposed surfaces of the pillar and the hemispherical silicon grains; and
forming on the dielectric layer an upper electrode using a second conductive layer.

23. The method according to claim 22, the step of forming the pillar further comprises:
forming a sacrificing layer on the first conductive layer using a substance having an etch rate that differs from that of the insulating layer;
patterning the sacrificing layer and the first conductive layer to remain in the contact hole and extends on a top surface portion of the insulating layer;
forming a first amorphous silicon layer doped with impurity ions at a first impurity density on the insulating layer including the remaining sacrificing layer and a first conductive layer pattern of the remaining first conductive layer;
forming on the first amorphous silicon layer a second amorphous silicon layer doped with impurity ions at a second impurity density higher than the first impurity density;
forming on the second amorphous silicon layer a third amorphous silicon layer doped with impurity ions at a third impurity density lower than the first impurity density;
patterning the first to third amorphous silicon layers to remain at sides of the remaining sacrificing layer and the first conductive layer pattern; and
removing the remaining sacrificing layer.

24. The method according to claim 22, wherein a lower electrode being a storage electrode of a capacitor is constructed with the remaining first conductive layer, the pillar, and the hemispherical silicon grains.

25. The method according to claim 22, wherein the first to third amorphous silicon layers and the hemispherical silicon grains are doped with negative impurity ions enabling to provide electric conductivity thereto.

26. The method according to claim 22, wherein the impurity ions are phosphorus ions.

27. The method according to claim 26, wherein the first impurity density of the phosphorus ions lies between 1.0E20 and 1.0E21 atoms/cm³, the second impurity density of the phosphorus ions is over 1.0E21 atoms/cm³, and the third impurity density of the phosphorus ions lies between 0.0 and 1.0E20 atoms/cm³.

28. The method according to claim 22, the step of forming a dielectric layer further comprises:
depositing a silicon nitride layer on surfaces of the hemispherical silicon grains and the pillar at a first temperature; and
oxidizing the silicon nitride layer at a second temperature at which the impurity ions diffuse naturally.

29. The method according to claim 22, the method further comprising the step of carrying out annealing on the hemispherical silicon grains and the pillar to diffuse the impurity ions therebetween.

30. The method according to claim 22, wherein the second conductive layer is formed of doped polysilicon.

31. The method according to claim 22, wherein the hemispherical silicon grains are formed by flowing SiH₄ gases on the exposed surfaces of the first conductive layer and the pillar.

32. The method according to claim 22, wherein the first to third amorphous silicon layers are formed of in-situ doped amorphous silicon at the first to third impurity densities, respectively.

33. The method according to claim 22, wherein the first to third amorphous silicon layers are formed by depositing undoped amorphous silicon and then by doping the undoped amorphous silicon at the first to third impurity densities, respectively.

34. A method of forming a capacitor for a semiconductor device comprising:
forming a lower electrode having a silicon layer with portions initially doped at different doping densities;
forming a plurality of protrusions selectively on the lower electrode according to the different doping densities;
forming a dielectric layer over the lower electrode and the protrusions; and
forming an upper electrode over the dielectric layer.

35. The method of claim 34, wherein the silicon layer is formed to have at least two different portions, each initially having a different doping density.

36. The method of claim 34, wherein forming the lower electrode having the silicon layer further comprises:
forming a first layer at a first doping density;
forming a second layer on the first layer at a second doping density; and
forming a third layer on the second layer at a third doping density.

37. The method of claim 36, wherein the second doping density is greater than the first doping density.

38. The method of claim 36, wherein the second doping density is greater than the third doping density.

39. The method of claim 36, wherein the third doping density is less than the first doping density.

40. The method of claim 36, wherein the third doping density is the same as the first doping density.

41. The method of claim 34, wherein the protrusions are formed by growing silicon particles on the lower electrode.

42. The method of claim 41, wherein the protrusions are formed on the lower electrode at portions having relatively low doping densities.

43. The method of claim 34, wherein the forming of the dielectric layer diffuses impurity ions in the silicon layer.

44. The method of clam 34, wherein a step of additionally doping the lower electrode after the protrusions are formed is not required.

45. A capacitor for a semiconductor device formed by a process comprising:
forming a lower electrode having a silicon layer with portions initially doped at different doping densities;
forming a plurality of protrusions selectively on the lower electrode according to the different doping densities;
forming a dielectric layer over the lower electrode and the protrusions; and
forming an upper electrode over the dielectric layer.

46. The capacitor of claim 45, wherein the silicon layer has at least two portions, each initially having a different doping density.
